(19) United States
(12) Patent Application Publication
(10) Pub. No.: US 2021/0050425 A1
(43) Pub. Date: Feb. 18, 2021

(54) SEMICONDUCTOR DEVICE WITH REDUCED PARASITIC CAPACITANCE

(71) Applicant: GLOBALFOUNDRIES INC., Grand Cayman (KY)

(72) Inventors: SHESH MANI PANDEY, Saratoga Springs, NY (US); JIEHUI SHU, Clifton Park, NY (US)

(21) Appl. No.: 16/540,042

(22) Filed: Aug. 13, 2019

(51) Int. Cl. H01L 29/417; H01L 29/40; H01L 29/49; H01L 29/51; H01L 29/66

(52) U.S. Cl. CPC H01L 29/41775; H01L 29/401; H01L 29/4966; H01L 29/4975; H01L 29/518; H01L 29/513; H01L 29/66545; H01L 29/41791; H01L 29/517; H01L 29/4983

(57) ABSTRACT

A semiconductor device comprises a gate stack structure having upper and lower sidewall portions and a bottom portion. The lower sidewall portions and the bottom portion having a high-k dielectric layer and a metal electrode layer that is positioned over the high-k dielectric layer. The upper sidewall portions having low-k dielectric layers over the lower sidewall portions. The low-k dielectric layers having side surfaces that are substantially coplanar with outer side surfaces of the high-k dielectric layer and are substantially coplanar with inner side surfaces of the metal electrode layer. A metal fill layer is over the metal electrode layer and the high-k dielectric layer in the lower sidewall portions and the bottom portion and between the low-k dielectric layers.

### FIELD OF THE INVENTION

The present disclosure relates generally to semiconductor devices with reduced parasitic capacitance, and more particularly to semiconductor devices with metal gates having reduced parasitic capacitance.

### BACKGROUND

As semiconductor devices continue to decrease in size, it becomes increasingly challenging to satisfy the demands for high performance. A major impediment for high performance in semiconductor devices is parasitic capacitance and semiconductor device scaling exacerbates the problem of parasitic capacitance. In particular, for a semiconductor device with a metal gate, the metal gate is typically separated from the trench silicide by various dielectric layers such as inter-level dielectric (ILD), spacers and gate dielectrics, and the parasitic capacitance between the metal gate and trench silicide for source and drain contacts will degrade device performance, especially the device speed. Hence, there is an urgent need for solutions to overcome the effects of parasitic capacitance.

### SUMMARY

In an aspect of the present disclosure, a semiconductor device is provided, the semiconductor device comprising a gate stack structure having upper and lower sidewall portions and a bottom portion. The lower sidewall portions and the bottom portion having a high dielectric constant (i.e., high-k) dielectric layer and a metal electrode layer that is positioned over the high-k dielectric layer. The upper sidewall portions having low dielectric constant (i.e., low-k) dielectric layers that are positioned over the lower sidewall portions. The low-k dielectric layers having side surfaces that are substantially coplanar with outer side surfaces of the high-k dielectric layer and are substantially coplanar with inner side surfaces of the metal electrode layer. A metal fill layer that is positioned over the metal electrode layer and the high-k dielectric layer in the lower sidewall portions and the bottom portion and positioned between the low-k dielectric layers in the upper sidewall portions.

In another aspect of the present disclosure, a semiconductor device is provided, the semiconductor device comprising a substrate and a gate stack structure having upper and lower sidewall portions and a bottom portion. The lower sidewall portions and the bottom portion having a high-k dielectric layer and a metal electrode layer over the high-k dielectric layer. The upper sidewall portions having low-k dielectric layers. The low-k dielectric layers having side surfaces that are substantially coplanar with outer side surfaces of the high-k dielectric layer and are substantially coplanar with inner side surfaces of the metal electrode layer. A metal fill layer over the metal electrode layer and the high-k dielectric layer in the lower sidewall portions and the bottom portion and between the low-k dielectric layers. Dielectric spacer structures adjacent the upper and lower sidewall portions of the gate stack structure.

In yet another aspect of the disclosure, a method to fabricate a semiconductor device is provided, the method comprising providing an opening in dielectric spacers, wherein the opening has sidewalls and a bottom surface. A high-k dielectric layer is deposited over the sidewalls and over the bottom surface of the opening. A metal electrode layer is deposited over the high-k dielectric layer. Upper portions of the high-k dielectric layer and the metal electrode layer are removed and leaving in place lower portions of the high-k dielectric layer and the metal electrode layer. Low-k dielectric layers are deposited to replace the removed upper portions of the high-k dielectric layer and the metal electrode layer. Side surfaces of the low-k dielectric layers are substantially coplanar with outer side surfaces of the lower portions of the high-k dielectric layer and are substantially coplanar with inner side surfaces of the lower portions of the metal electrode layer.

Numerous advantages may be derived from the embodiments described above. The low-k dielectric layers in upper sidewall portions of a gate stack structure may separate a conductive trench silicide from a conductive gate metal fill. The trench silicide may function as source and/or drain contacts. Thus, a separation distance between the conductive trench silicide and a conductive gate metal layer is increased leading to a lower parasitic capacitance. In addition, the use of low-k dielectric layers in the upper portions of the gate stack structure instead of a high-k dielectric layer also leads to a lower parasitic capacitance.

### BRIEF DESCRIPTION OF THE DRAWINGS

The disclosed embodiments will be better understood from a reading of the following detailed description, taken in conjunction with the accompanying drawings:

FIG. 1A is a cross-sectional view of a partially completed semiconductor device in accordance with an embodiment of the disclosure.

FIG. 1B is a cross-sectional view of a partially completed semiconductor device after depositing a capping metal layer in accordance with an embodiment of the disclosure.

FIG. 1C is a cross-sectional view of a partially completed semiconductor device after depositing a metal electrode layer in accordance with an embodiment of the disclosure.

FIG. 1D is a cross-sectional view of a partially completed semiconductor device after depositing a sacrificial material layer in accordance with an embodiment of the disclosure.

FIG. 1E is a cross-sectional view of a partially completed semiconductor device after planarization of the semiconductor device in accordance with an embodiment of the disclosure.

FIG. 1F is a cross-sectional view of a partially completed semiconductor device after removing a high-k dielectric layer, the capping metal layer and the metal electrode layer from upper portions of the gate stack structure in accordance with an embodiment of the disclosure.

FIG. 1G is a cross-sectional view of a partially completed semiconductor device after depositing a low-k dielectric layer in accordance with an embodiment of the disclosure.

FIG. 1H is a cross-sectional view of a partially completed semiconductor device after planarization of the semiconductor device in accordance with an embodiment of the disclosure.

FIG. 1I is a cross-sectional view of a partially completed semiconductor device after removal of the sacrificial material layer in accordance with an embodiment of the disclosure.

FIG. 1J is a cross-sectional view of a partially completed semiconductor device after deposition of a barrier metal layer in accordance with an embodiment of the disclosure.

FIG. 1K is a cross-sectional view of a partially completed semiconductor device after deposition of a metal contact layer in accordance with an embodiment of the disclosure.

FIG. 1L is a cross-sectional view of a partially completed semiconductor device after planarization of the semiconductor device in accordance with an embodiment of the disclosure.

FIG. 1M is a cross-sectional view of a partially completed semiconductor device after formation of trench silicide in accordance with an embodiment of the disclosure.

FIG. 2A shows a partially completed semiconductor device in accordance with another embodiment of the present disclosure in accordance with an embodiment of the disclosure.

FIG. 2B is a cross-sectional view of a partially completed semiconductor device after deposition of a sacrificial material layer over a metal electrode layer in accordance with an embodiment of the disclosure.

FIG. 2C is a cross-sectional view of a partially completed semiconductor device after removal of a work function metal layer, a capping metal layer, a metal electrode layer and a high-k dielectric layer from upper portions of the gate stack structure in accordance with an embodiment of the disclosure.

FIG. 2D is a cross-sectional view of a partially completed semiconductor device after deposition of low-k dielectric layers in accordance with an embodiment of the disclosure.

FIG. 2E is a cross-sectional view of a partially completed semiconductor device after removal of the sacrificial material in accordance with an embodiment of the disclosure.

FIG. 2F is a cross-sectional view of a partially completed semiconductor device after deposition of a barrier metal layer and a metal contact layer over the barrier metal layer in accordance with an embodiment of the disclosure.

For simplicity and clarity of illustration, the drawings illustrate the general manner of construction, and certain descriptions and details of well-known features and techniques may be omitted to avoid unnecessarily obscuring the discussion of the described embodiments of the device. Additionally, elements in the drawings are not necessarily drawn to scale. For example, the dimensions of some of the elements in the drawings may be exaggerated relative to other elements to help improve understanding of embodiments of the device. The same reference numerals in different drawings denote the same elements, while similar reference numerals may, but do not necessarily, denote similar elements.

### DETAILED DESCRIPTION

The following detailed description is exemplary in nature and is not intended to limit the device or the application and uses of the device. Furthermore, there is no intention to be bound by any theory presented in the preceding background of the device or the following detailed description.

The disclosure relates to semiconductor devices with reduced parasitic capacitance between the metal gate and the trench silicide for source and drain contacts and the associated method of fabrication. The semiconductor devices may be transistor devices such as complementary metal-oxide-semiconductor (CMOS) devices. A CMOS device includes a P-type metal-oxide-semiconductor (PMOS) device and/or an N-type metal-oxide-semiconductor (NMOS) device.

The various embodiments of the transistor devices in this present disclosure may be fabricated with gate first or gate last transistor fabrication process techniques. In a gate first process, conductive layers over first structure areas (e.g. NMOS areas, etc.) and second structure areas (e.g. PMOS areas, etc.) are formed and patterned to form gate structures followed by conventional CMOS processing, including formation of source and drain regions, formation of spacers and deposition of ILD material. In a gate last process, dummy gate structures are formed, followed by conventional CMOS processing, including formation of the source and drain regions, formation of spacers and deposition of ILD material. Thereafter, the dummy gate structures are removed, followed by conventional formation of replacement gate structures.

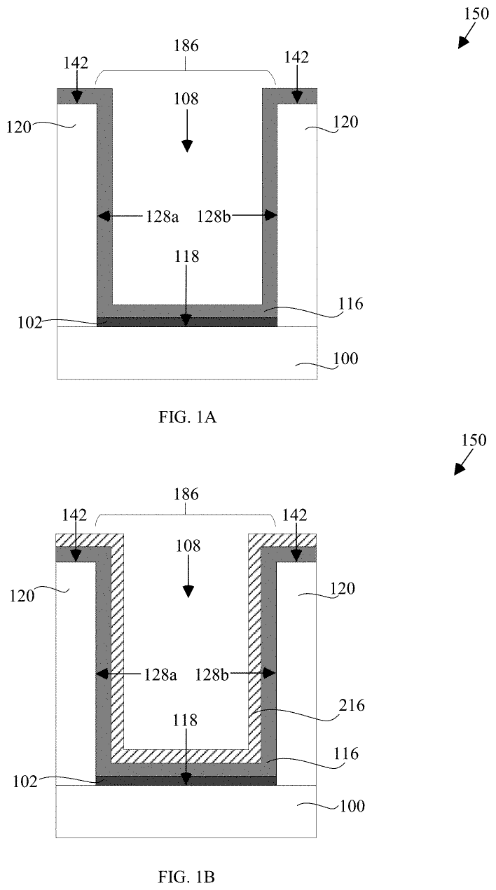

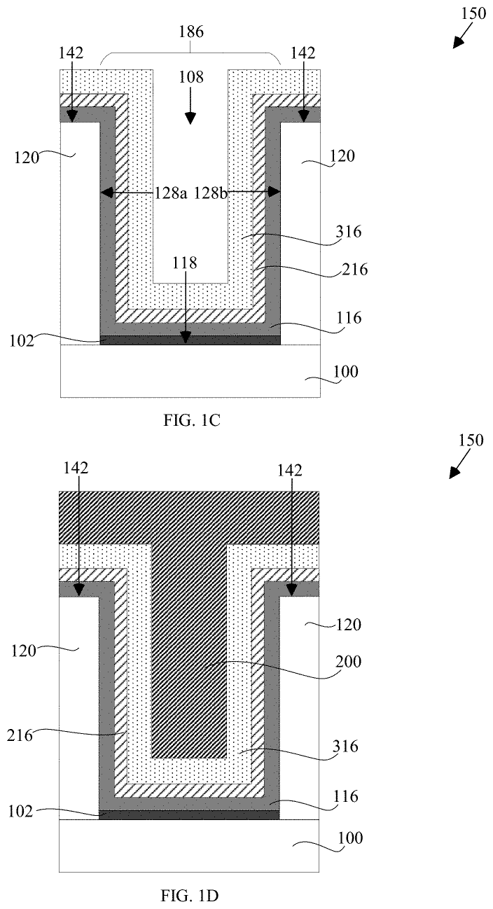

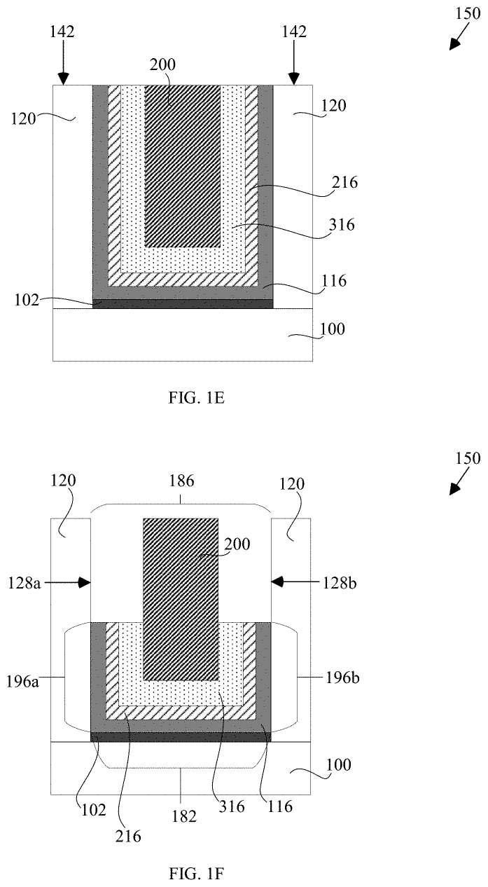

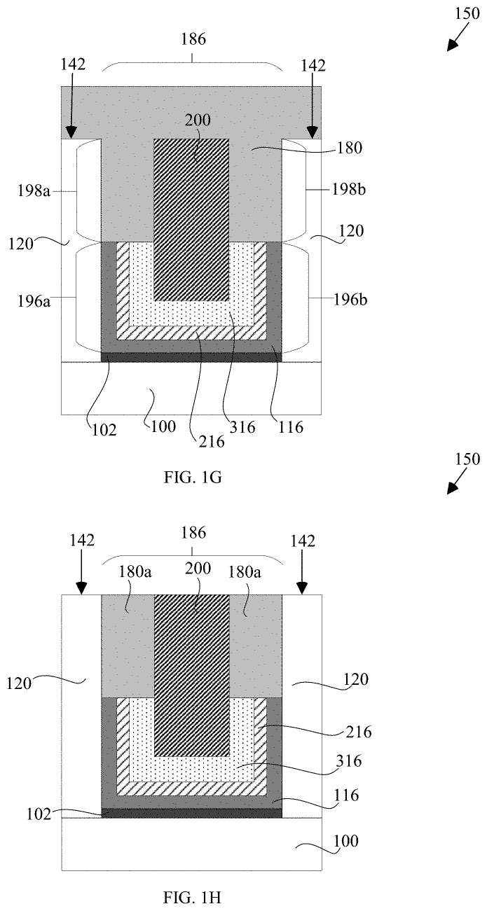

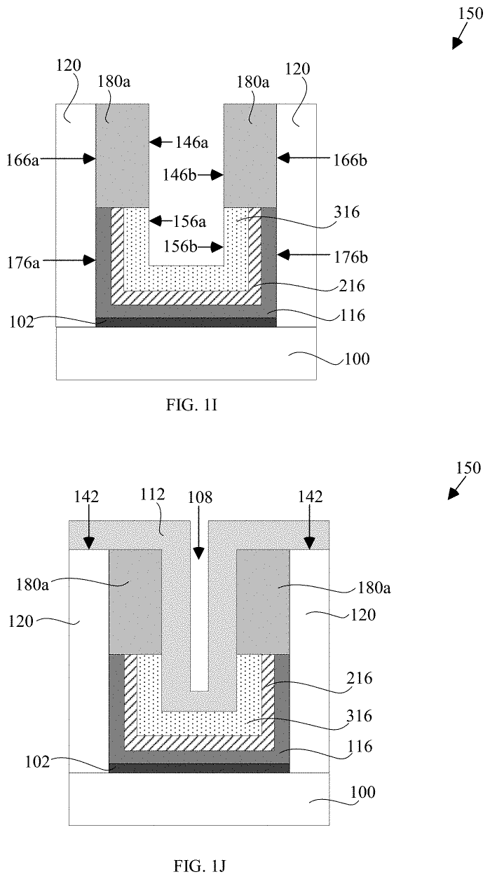

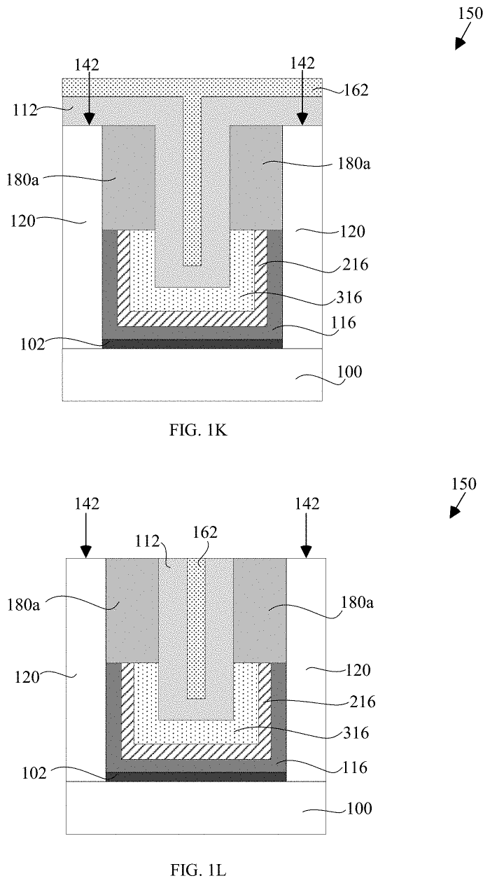

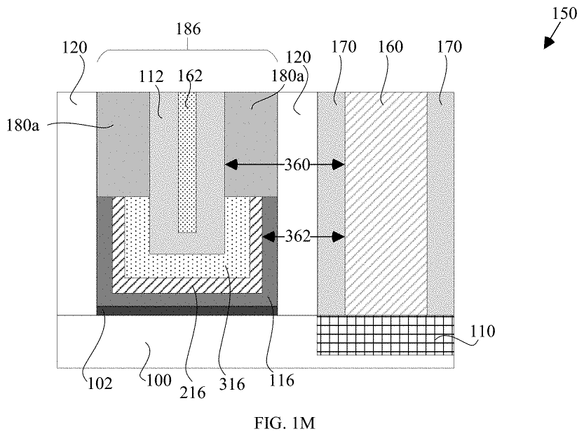

FIG. 1A is a cross-sectional view of a partially completed semiconductor device 150 in accordance with an embodiment of the present disclosure. The semiconductor device 150 comprises an opening 108 in dielectric spacers 120. The opening 108 has sidewalls 128a and 128b and a bottom surface 118. The bottom surface 118 of the opening may be a substrate 100. An interfacial layer 102 may be grown on the bottom surface 118 of the opening 108. A high-k dielectric layer 116 may be deposited over the sidewalls 128a and 128b and over the bottom surface 118 of the opening 108. The high-k dielectric layer 116 may also be deposited over the top surfaces 142 of the semiconductor device 150. The high-k dielectric layer 116 may form a first layer of a gate stack structure 186.

In an embodiment, the interfacial layer 102 may be an oxide layer, such as silicon dioxide or SiO₂. The SiO₂ interfacial layer 102 provides a stable interface between the substrate 100 and the high-k dielectric layer 116.

The term “high-k” as used herein refers to a material having a dielectric constant that is greater than 10. The high-k dielectric layer 116 may include, but is not limited to, hafnium oxide (HfO₂), zirconium oxide (ZrO₂), lanthanum oxide (La₂O₃), aluminum oxide (Al₂O₃), titanium oxide (TiO₂), strontium titanium oxide (SrTiO₃), lanthanum aluminum oxide (LaAlO₃), yttrium oxide (Y₂O₃), hafnium oxynitride (HfOₓN_{y}), zirconium oxynitride (ZrOₓN_{y}), lanthanum oxynitride (La₂OₓN_{y}), aluminum oxynitride (Al₂OₓN_{y}), titanium oxynitride (TiOₓN_{y}), strontium titanium oxynitride (SrTiOₓN_{y}), lanthanum aluminum oxynitride (LaAlOₓN_{y}), yttrium oxynitride (Y₂OₓN_{y}), a silicate thereof, and an alloy thereof. Each value of x is independently from 0.5 to 3 and each value of y is independently from 0 to 2. The high-k dielectric layer 116 may have a thickness in the range of about 1 nm to about 5 nm, and preferably about 1 nm to about 3 nm.

In accordance with an embodiment of this disclosure, the high-k dielectric layer 116 may be a gate dielectric layer. The high-k dielectric layer 116 may be formed by conventional deposition processes, such as chemical vapor deposition (CVD), physical vapor deposition (PVD), molecular beam deposition (MBD), pulsed laser deposition (PLD), liquid source misted chemical deposition (LSMCD), atomic layer deposition (ALD), etc. However, a highly conformal deposition process is preferred for depositing the high-k dielectric layer 116; for example, an ALD process or a highly-controlled CVD process.

The substrate 100 may be made of any suitable semiconductor material, such as silicon, germanium, or silicon germanium. In an embodiment, the substrate 100 may be represented as a fin. In an alternative embodiment, the substrate 100 may be represented as a doped layer on a top surface of a bulk semiconductor substrate or a semiconductor-on-insulator layer. It should also be understood that the present disclosure can be applied to any type of transistor device architecture, such as a three-dimensional device architecture (e.g., FinFETs), or a planar device architecture (e.g., complementary metal oxide semiconductor (CMOS) devices), semiconductor-on-insulator (SOI) devices).

The dielectric spacers 120 may be formed of a low-k material, such as silicon nitride, silicon oxycarbonitride (SiOCN), silicon-boron-carbide-nitride (SiBCN) and silicon oxycarbide (SiOC). The term “low-k” as used herein refers to a material having a dielectric constant that is lower than 7. The silicon nitride layer for the dielectric spacers 120 may be deposited by chemical vapor deposition. The dielectric spacers 120 may be formed by anisotropic etching of the deposited silicon nitride layer.

The term “anisotropic etching” refers to etching which does not proceed in all directions at the same rate. If etching proceeds exclusively in one direction (e.g., only vertically), the etching process is said to be completely anisotropic.

FIG. 1B follows FIG. 1A after depositing a capping metal layer 216 over the high-k dielectric layer 116 in accordance with an embodiment of the disclosure. The capping metal layer 216 may be deposited over the bottom surface 118 and over the sidewalls 128a and 128b of the opening 108. The capping metal layer 216 may also be deposited over the top surfaces 142 of the semiconductor device 150. The capping metal layer 216 may form a second layer of the gate stack structure 186. In an embodiment, the capping metal layer 216 may be made of titanium nitride or TiN. In an alternative embodiment, the capping metal layer 216 may be made of tantalum nitride (TaN), titanium silicon nitride (TiSiN) or any other suitable metal. The capping metal layer 216 may have a thickness in the range of 5 Å to 50 Å. In an embodiment, the capping metal layer 216 may have a thickness of 18 Å. The work function metal layer and the capping metal layer 216 may be deposited by conventional deposition processes. However, a highly conformal process is preferred, such as an ALD process or a highly-controlled CVD process.

FIG. 1C follows FIG. 1B after depositing a metal electrode layer 316 over the capping metal layer 216 in accordance with an embodiment of the disclosure. The metal electrode layer 316 may be deposited over the bottom surface 118 and over the sidewalls 128a and 128b of the opening 108. The metal electrode layer 316 may also be deposited over the top surfaces 142 of the semiconductor device 150. The metal electrode layer 316 may form a third layer of the gate stack structure 186. In an embodiment, the metal electrode layer 316 may be made of aluminum-doped titanium carbide (TiAlC). In an alternative embodiment, the metal electrode layer 316 may be made of aluminum (Al) or titanium aluminide (TiAl). The metal electrode layer 316 may have a thickness in the range of 10 Å to 60 Å. In an embodiment, the metal electrode layer may have a thickness of 40 Å. The metal electrode layer 316 may be deposited by conventional deposition processes. However, a highly conformal process is preferred, such as an ALD process or a highly-controlled CVD process.

FIG. 1D follows FIG. 1C after deposition of a sacrificial material layer 200 over the metal electrode layer 316, filling up the opening 108 in accordance with an embodiment of the disclosure. The sacrificial material layer 200 may also be deposited over the top surfaces 142 of the semiconductor device 150. In an embodiment, the sacrificial material layer 200 may be made of amorphous silicon. In an alternative embodiment, the sacrificial material layer 200 may be made of a metal oxide such as titanium dioxide (TiO₂) or aluminum oxide (Al₂O₃). The sacrificial material layer 200 may be deposited by conventional deposition processes. However, a highly conformal process is preferred, such as an ALD process or a highly-controlled CVD process.

FIG. 1E follows FIG. 1D after planarization of the semiconductor device 150 in accordance with an embodiment of the disclosure. In particular, the sacrificial material layer 200, the metal electrode layer 316, the capping metal layer 216 and the high-k dielectric layer 116 may be removed from the top surfaces 142 of the semiconductor device 150. The top surfaces 142 of the semiconductor device 150 may be coplanar with a top surface of the sacrificial material layer 200, the metal electrode layer 316, the capping metal layer 216 and the high-k dielectric layer 116. The planarization process may be a chemical mechanical planarization (CMP) process.

FIG. 1F follows FIG. 1E after removing upper portions of the high-k dielectric layer 116, the capping metal layer 216 and the metal electrode layer 316 and leaving in place lower portions 196a and 196b and a bottom portion 182 of the high-k dielectric layer 116, the capping metal layer 216 and the metal electrode layer 316 in accordance with an embodiment of the disclosure. In an embodiment, the lower portions 196a and 196b may be lower sidewall portions of the gate stack structure 186. The removal process may be by selective etching.

The term “selective etching” means a chemical etching method which can selectively remove a target layer without attacking the layer beneath the target layer, termed a stop layer for this reason, by adjusting the composition of the chemical solution and, as a result, adjusting the etching rates between the target layer and the stop layer.

FIG. 1G follows FIG. 1F after deposition of a low-k dielectric layer 180 to replace the removed upper portions of the high-k dielectric layer 116, the capping metal layer 216 and the metal electrode layer 316 in accordance with an embodiment of the disclosure. The low-k dielectric layer 180 forms upper portions 198a and 198b of the gate stack structure 186. The upper portions 198a and 198b, respectively, of the gate stack structure 186 are over the lower portions 196a and 196b, respectively, of the gate stack structure 186. In an embodiment, the upper portions 198a and 198b may be upper sidewall portions of the gate stack structure 186. The low-k dielectric layer 180 may also be deposited on the top surfaces 142 of the semiconductor device 150 and on the top surface of the sacrificial material layer 200. In an embodiment, the low-k dielectric layer 180 may include, but is not limited to SiOCN, SiBCN, silicon carbon nitride (SiCN), SiOC or silicon carbide (SiC). The low-k dielectric layer 180 may be deposited by conventional deposition processes. However, a highly conformal process is preferred, such as an ALD process or a highly-controlled CVD process.

FIG. 1H follows FIG. 1G after planarization of the semiconductor device 150 in accordance with an embodiment of the disclosure. In particular, a portion of the low-k dielectric layer 180 may be removed from the top surfaces 142 of the semiconductor device 150. Top surfaces of the remaining low-k dielectric layers 180a may be coplanar with the top surface 142. The planarization process may be a CMP process.

FIG. 1I follows FIG. 1H after removal of the sacrificial material layer 200 in accordance with an embodiment of the disclosure. The sacrificial material layer 200 may be removed by a selective etching process. Inner side surfaces 146a and 146b, respectively, of the low-k dielectric layers 180a may be substantially coplanar with inner side surfaces 156a and 156b, respectively, of the lower portions of the metal electrode layer 316. Outer side surfaces 166a and 166b, respectively, of the low-k dielectric layers 180a may be substantially coplanar with outer side surfaces, 176a and 176b, respectively, of the lower portions of the high-k dielectric layer 116.

FIG. 1J follows FIG. 1I after deposition of a barrier metal layer 112 to replace the removed sacrificial material layer 200 in accordance with an embodiment of the disclosure. The barrier metal layer 112 may be deposited over the low-k dielectric layers 180a and the metal electrode layer 316. The barrier metal layer 112 may also be deposited on the top surfaces 142 of the semiconductor device 150. In an embodiment, the barrier metal layer 112 may be made of TiN. In an alternative embodiment, the barrier metal layer 112 may be made of TaN. The thickness of the barrier metal layer 112 may be in a range of 20 Å to 100 Å. In an embodiment, the barrier metal layer 112 may have a thickness of 60 Å. The barrier metal layer 112 may be deposited by conventional deposition processes. However, a highly conformal process is preferred, such as an ALD process or a highly-controlled CVD process.

FIG. 1K follows FIG. 1J after deposition of a metal contact layer 162 over the barrier metal layer 112 to fill up the opening 108 in accordance with an embodiment of the disclosure. The metal contact layer 162 may also be deposited over the top surfaces 142 of the semiconductor device 150. In an embodiment, the metal contact layer 162 may be made of tungsten (W). In an alternative embodiment, the metal contact layer 162 may be made of cobalt (Co), ruthenium (Ru), Al or copper (Cu). The metal contact layer 162 may be deposited by conventional deposition processes or electrochemical plating (ECP). However, a highly conformal process is preferred, such as an ALD process or a highly-controlled CVD process.

FIG. 1L follows FIG. 1K after planarization of the semiconductor device 150 in accordance with an embodiment of the disclosure. In particular, the planarization process removes the barrier metal layer 112 and the metal contact layer 162 from the top surfaces of the low-k dielectric layers 180a and from the top surfaces 142 of the semiconductor device 150. The top surfaces of the low-k dielectric layers 180a are coplanar with a top surface of the barrier metal layer 112, a top surface of the metal contact layer 162 and the top surfaces 142 of the semiconductor device 150 after the planarization process. The barrier metal layer 112 and the metal contact layer 162 may be collectively referred to as a metal fill layer. In an embodiment, the metal fill layer may be a gate metal fill layer. The planarization process may be a CMP process. The semiconductor device 150 may be an n-channel transistor.

FIG. 1M follows FIG. 1L after formation of a trench silicide 160 and a doped source and/or drain region 110 over the semiconductor substrate 100 in accordance with an embodiment of the disclosure. The trench silicide 160 may be separated from the gate metal fill layer by the low-k dielectric layers 180a, the dielectric spacer 120 and an inter-level dielectric (ILD) layer 170. Hence, a separation distance 360 between the trench silicide 160 and the conductive gate metal fill layer is longer than a separation distance 362 between the trench silicide 160 and the conductive capping metal layer 216. Thus, replacing the high-k dielectric layer 116, capping metal layer 216 and the metal electrode layer 316 with low-k dielectric layers 180a in the upper portions of the gate stack structure 186 results in a lower parasitic capacitance of the semiconductor device 150.

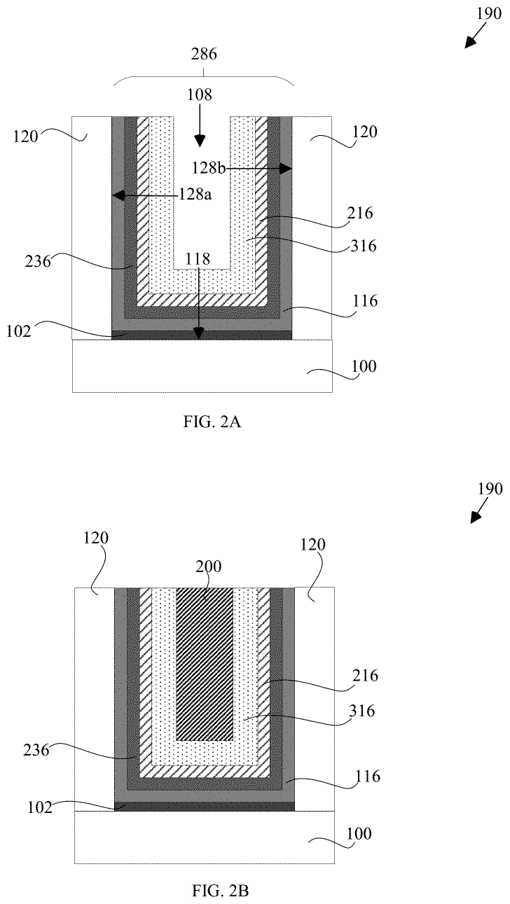

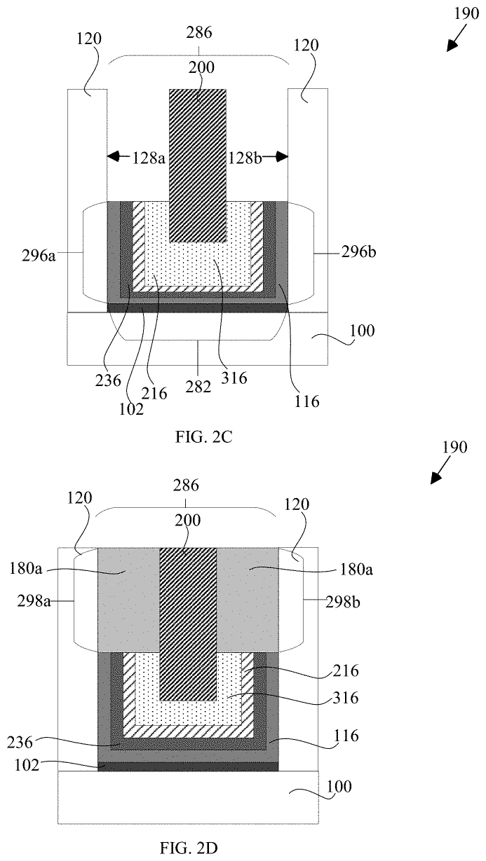

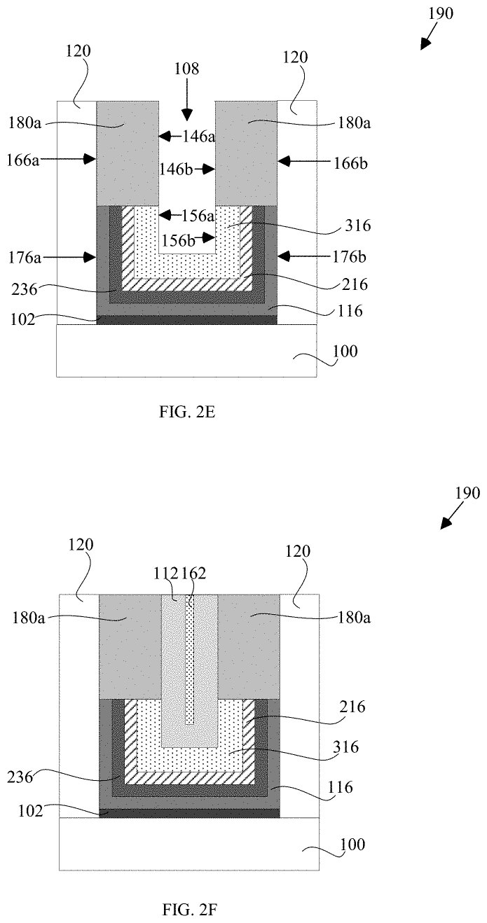

FIG. 2A shows a partially completed semiconductor device 190 in accordance with an embodiment of the present disclosure. The semiconductor device 190 may be a p-channel transistor. The same reference numbers used in FIGS. 1A to 1M are also used in FIG. 2A to refer to identical features.

As shown in FIG. 2A, the semiconductor device 190 may include an additional layer such as a work function metal layer 236 as compared to FIG. 1C. The semiconductor device 190 may be fabricated by providing dielectric spacers 120 on a substrate 100. An interfacial layer 102 may be grown on the substrate 100. A high-k dielectric layer 116 may be deposited over sidewalls 128a and 128b and a bottom surface 118 of an opening 108 in the dielectric spacers 120 to form a first layer of a gate stack structure 286. A work function metal layer 236 may be deposited over the high-k dielectric layer 116 to form a second layer of the gate stack structure 286. A capping metal layer 216 may subsequently be deposited over the work function metal layer 236 to form a third layer of the gate stack structure 286. A metal electrode layer 316 may be deposited over the capping metal layer 216 to form a fourth layer of the gate stack structure 286. The high-k dielectric layer 116, the work function metal layer 236, the capping metal layer 216 and the metal electrode layer 316 may also be deposited over top surfaces of the dielectric spacers 120 (not shown). The semiconductor device 190 may subsequently be planarized by a CMP process.

In an embodiment, the work function metal layer 236 may be made of TiN. In an alternative embodiment, the work function metal layer 236 may be made of TaN, TiSiN. The thickness of the work function metal layer 236 ranges between 5 Å and 50 Å. In an embodiment, the thickness of the work function metal layer 236 may be 13 Å. The work function metal layer 236 may be deposited by conventional deposition processes. However, a highly conformal process is preferred, such as an ALD process or a highly-controlled CVD process.

FIG. 2B follows FIG. 2A after the deposition of a sacrificial material layer 200 over the metal electrode layer 316 filling up the opening 108 in accordance with an embodiment of the disclosure. The sacrificial material layer 200 may also be deposited over top surfaces of the high-k dielectric layer 116, the work function metal layer 236, the capping metal layer 216, the metal electrode layer 316 and the dielectric spacers 120 (not shown). The semiconductor device 190 may subsequently be planarized by a CMP process.

FIG. 2C follows FIG. 2B after removal of upper portions of the work function metal layer 236, the capping metal layer 216, the metal electrode layer 316 and the high-k dielectric layer 116 and leaving in place lower portions 296a and 296b and a bottom portion 282 of the work function metal layer 236, the capping metal layer 216, the metal electrode layer 316 and the high-k dielectric layer 116 in accordance with an embodiment of the disclosure. The removal process may be by selective etching. In an embodiment, the lower portions 296a and 296b may be lower sidewall portions of the gate stack structure 286.

FIG. 2D follows FIG. 2C after deposition of low-k dielectric layers 180a to form upper portions 298a and 298b of the gate stack structure 286 in accordance with an embodiment of the disclosure. In an embodiment, the upper portions 298a and 298b may be upper sidewall portions. The low-k dielectric layers may also be deposited over top surfaces of the semiconductor device 190 and a top surface of the sacrificial material 200 (not shown). The semiconductor device 190 may subsequently be planarized by a CMP process.

FIG. 2E follows FIG. 2D after removal of the sacrificial material 200 in accordance with an embodiment of the disclosure. Inner side surfaces 146a and 146b, respectively, of the low-k dielectric layers 180a may be substantially coplanar with inner side surfaces 156a and 156b, respectively, of the lower portions of the metal electrode layer 316. Outer side surfaces 166a and 166b, respectively, of the low-k dielectric layers 180a may be substantially coplanar with outer side surfaces, 176a and 176b, respectively, of the lower portions of the high-k dielectric layer 116.

FIG. 2F follows FIG. 2E after deposition of a barrier metal layer 112 and a metal contact layer 162 over the barrier metal layer 112 in accordance with an embodiment of the disclosure. The barrier metal layer 112 may be deposited over the metal electrode layer 316 and between the low-k dielectric layers 180a. The barrier metal layer 112 and the metal contact layer 162 may also be deposited over top surfaces of the low-k dielectric layers 180a and over top surfaces of the semiconductor device 190 (not shown). The semiconductor device 190 may subsequently be planarized by a CMP process.

The terms “first”, “second”, “third”, and the like in the description and in the claims, if any, are used for distinguishing between similar elements and not necessarily for describing a particular sequential or chronological order. It is to be understood that the terms so used are interchangeable under appropriate circumstances such that the embodiments of the device described herein are, for example, capable of operation in sequences other than those illustrated or otherwise described herein. The terms “left”, “right”, “front”, “back”, “top”, “bottom”, “over”, “under”, and the like in the description and in the claims, if any, are used for descriptive purposes and not necessarily for describing permanent relative positions. It is to be understood that the terms so used are interchangeable under appropriate circumstances such that the embodiments of the device described herein are, for example, capable of operation in other orientations than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method. Furthermore, the terms “comprise”, “include”, “have”, and any variations thereof, are intended to cover a non-exclusive inclusion, such that a process, method, article, or device that comprises a list of elements is not necessarily limited to those elements, but may include other elements not expressly listed or inherent to such process, method, article, or device.

While several exemplary embodiments have been presented in the above detailed description of the device, it should be appreciated that number of variations exist. It should further be appreciated that the embodiments are only examples, and are not intended to limit the scope, applicability, dimensions, or configuration of the device in any way. Rather, the above detailed description will provide those skilled in the art with a convenient road map for implementing an exemplary embodiment of the device, it being understood that various changes may be made in the function and arrangement of elements and method of fabrication described in an exemplary embodiment without departing from the scope of this disclosure as set forth in the appended claims.

What is claimed is:

1. A semiconductor device comprising:
a gate stack structure having upper and lower sidewall portions and a bottom portion;
the lower sidewall portions and the bottom portion having a high-k dielectric layer and a metal electrode layer that is positioned over the high-k dielectric layer;
the upper sidewall portions having low-k dielectric layers that are positioned over the lower sidewall portions;
the low-k dielectric layers having side surfaces that are substantially coplanar with outer side surfaces of the high-k dielectric layer and are substantially coplanar with inner side surfaces of the metal electrode layer; and
a metal fill layer that is positioned over the metal electrode layer and the high-k dielectric layer in the lower sidewall portions and the bottom portion and positioned between the low-k dielectric layers in the upper sidewall portions.

2. The device of claim 1 wherein the lower sidewall portions and the bottom portion further comprises a capping metal layer over the high-k dielectric layer, wherein the capping metal layer separates the high-k dielectric layer from the metal electrode layer.

3. The device of claim 1 wherein upper top surfaces of the low-k dielectric layers are coplanar with an upper top surface of the metal fill layer.

4. The device of claim 1, wherein the low-k dielectric layers comprise silicon oxycarbonitride (SiOCN), silicon-boron-carbide-nitride (SiBCN), silicon carbon nitride (SiCN), silicon oxycarbide (SiOC) or silicon carbide (SiC).

5. The device of claim 2, wherein the capping metal layer comprises titanium nitride (TiN), tantalum nitride (TaN) or titanium silicon nitride (TiSiN).

6. The device of claim 1, wherein the metal fill layer comprises a barrier metal layer and a metal contact layer over the barrier metal layer.

7. The device of claim 6, wherein the barrier metal layer comprises TiN or TaN.

8. The device of claim 6, wherein the metal contact layer comprises tungsten (W), cobalt (Co), ruthenium (Ru), aluminum (Al) or copper (Cu).

9. The device of claim 1, wherein the metal electrode layer comprises aluminum-doped titanium carbide (TiAlC), Al or titanium aluminide (TiAl).

10. The device of claim 1 further comprising an interfacial layer at the bottom portion of the gate stack structure.

11. The device of claim 2 further comprising:
a work function metal layer over the high-k dielectric layer, wherein the work function metal layer separates the high-k dielectric layer from the capping metal layer; and
the device is a p-channel transistor.

12. The device of claim 11, wherein the work function metal layer comprises TiN, TaN or TiSiN.

13. A semiconductor device comprising:
a substrate;
a gate stack structure having upper and lower sidewall portions and a bottom portion;
the lower sidewall portions and the bottom portion having a high-k dielectric layer and a metal electrode layer over the high-k dielectric layer;
the upper sidewall portions having low-k dielectric layers;
the low-k dielectric layers having side surfaces that are substantially coplanar with outer side surfaces of the high-k dielectric layer and are substantially coplanar with inner side surfaces of the metal electrode layer;
a metal fill layer over the metal electrode layer and the high-k dielectric layer in the lower sidewall portions and the bottom portion and between the low-k dielectric layers; and
dielectric spacer structures adjacent the upper and lower sidewall portions of the gate stack structure.

14. The semiconductor device of claim 13 further comprising:
a trench silicide over the substrate, wherein the trench silicide is separated by the dielectric spacer structure and the low-k dielectric layer from the metal fill layer in the gate stack structure.

15. The semiconductor device of claim 14 further comprising:
an inter-level dielectric layer over the substrate, wherein the inter-level dielectric layer separates the trench silicide from the gate stack structure.

16. A method of fabricating a semiconductor device, the method comprising:
providing an opening in dielectric spacers, wherein the opening has sidewalls and a bottom surface;
depositing a high-k dielectric layer over the sidewalls and over the bottom surface of the opening;
depositing a metal electrode layer over the high-k dielectric layer;
removing upper portions of the high-k dielectric layer and the metal electrode layer and leaving in place lower portions of the high-k dielectric layer and the metal electrode layer; and
depositing low-k dielectric layers to replace the removed upper portions of the high-k dielectric layer and the metal electrode layer, wherein side surfaces of the low-k dielectric layers are substantially coplanar with outer side surfaces of the lower portions of the high-k dielectric layer and are substantially coplanar with inner side surfaces of the lower portions of the metal electrode layer.

17. The method of claim 16 further comprising:
depositing a sacrificial material layer over the metal electrode layer to fill up the opening prior to removing the upper portions of the high-k dielectric layer and the metal electrode layer;
removing the sacrificial material layer after the deposition of the low-k dielectric layers; and
depositing a metal fill layer over the metal electrode layer and between the low-k dielectric layers to replace the removed sacrificial material layer.

18. The method of claim 16 further comprising:
depositing a work function metal layer over the high-k dielectric layer prior to depositing the metal electrode layer.

19. The method of claim 18 further comprising:
depositing a capping metal layer over the work function metal layer prior to depositing a metal electrode layer.

20. The method of claim 19 further comprising:
removing upper portions of the work function metal layer and the capping metal layer together with the upper portions of the high-k dielectric layer and the metal electrode layer and leaving in place lower portions of the work function metal layer and the capping metal layer.
